(19) United States
(12) Patent Application Publication
(10) Pub. No.: US 2026/0130176 A1
(43) Pub. Date: May 7, 2026

(54) LAMINATED SHEET, METHOD FOR MANUFACTURING LAMINATED SHEET, METHOD FOR PROCESSING WORKPIECE, AND METHOD FOR MANUFACTURING DEVICE CHIP

(71) Applicant: DISCO CORPORATION, Tokyo (JP)

(72) Inventors: Norihisa ARIFUKU, Tokyo (JP); Masamitsu KIMURA, Tokyo (JP); Shingo MOTOIKE, Tokyo (JP)

(21) Appl. No.: 19/364,397

(22) Filed: Oct. 21, 2025

(30) Foreign Application Priority Data
Nov. 6, 2024 (JP) 2024-194456
Jun. 26, 2025 (JP) 2025-108342

(51) Int. Cl. H01L 21/683; B32B 7/022; B32B 9/04; H01L 21/304; H01L 21/78

(52) U.S. Cl. CPC H10P 72/7402; B32B 7/022; B32B 9/04; H10P 52/00; H10P 54/00; B32B 2250/02; B32B 2307/54; B32B 2457/14

(57) ABSTRACT

A laminated sheet includes: a first layer having a storage modulus of 1.0E+9 Pa or more and 1.0E+10 Pa or less in a tensile direction under a condition where a frequency of 1 Hz is applied in an environment of 50° C.; and a second layer laminated on the first layer and having a storage modulus of 1.0E+6 Pa or more and 1.0E+8 Pa or less in the tensile direction under the condition where the frequency of 1 Hz is applied in the environment of 50° C. A difference in a solubility parameter between the first layer and the second layer is 3.0 or less. The first layer and the second layer are laminated without an adhesive layer interposed therebetween.

### CROSS-REFERENCE TO RELATED APPLICATION(S)

The present application claims priority to and incorporates by reference the entire contents of Japanese Patent Application No. 2024-194456 filed in Japan on Nov. 6, 2024 and Japanese Patent Application No. 2025-108342 filed in Japan on Jun. 26, 2025.

### TECHNICAL FIELD

The present disclosure relates to a laminated sheet, a method for manufacturing the laminated sheet, a method for processing a workpiece, and a method for manufacturing a device chip.

### BACKGROUND

In the manufacturing process of the device chip, the back surface of a wafer, which has a front surface on which a device is formed, is ground to thin the wafer, and dicing is performed along streets to divide the wafer into individual device chips. In grinding the back surface of the wafer, the front surface of the wafer is protected with a sheet for surface protection, and then the back side is ground while the sheet is held on the holding surface of a holding table (see JP 2019 029543 A).

When the wafer surface has irregularities such as bumps, if the surface protection sheet is a single layer, the surface protection sheet has irregularities that follows the irregularities such as bumps, resulting in insufficient protection of the wafer surface and causing thickness variation during grinding. Even when the surface protection sheet is a laminated sheet in which two or more layers of sheet are laminated, if the sheets are bonded to each other with an adhesive, the thickness variation of an adhesive layer directly leads to thickness variation during grinding.

### SUMMARY

According to an aspect of the present disclosure, a laminated sheet includes: a first layer having a storage modulus of 1.0E+9 Pa or more and 1.0E+10 Pa or less in a tensile direction under a condition where a frequency of 1 Hz is applied in an environment of 50° C.; and a second layer laminated on the first layer and having a storage modulus of 1.0E+6 Pa or more and 1.0E+8 Pa or less in the tensile direction under the condition where the frequency of 1 Hz is applied in the environment of 50° C. A difference in a solubility parameter between the first layer and the second layer is 3.0 or less. The first layer and the second layer are laminated without an adhesive layer interposed therebetween.

According to another aspect of the present disclosure, a method is for manufacturing a laminated sheet. The method includes: preparing a first sheet and a second sheet, the first sheet having a storage modulus of 1.0E+9 Pa or more and 1.0E+10 Pa or less in a tensile direction under a condition where a frequency of 1 Hz is applied in an environment of 50° C., and the second sheet having a storage modulus of 1.0E+6 Pa or more and 1.0E+8 Pa or less in the tensile direction under the condition where the frequency of 1 Hz is applied in the environment of 50° C. and having a difference in a solubility parameter from the first sheet of 3.0 or less; and laminating the first sheet and the second sheet without an adhesive interposed therebetween, and compressing and bonding the first sheet and the second sheet while melting an interface therebetween by heating.

### BRIEF DESCRIPTION OF THE DRAWINGS

FIG. 1 is a cross-sectional view illustrating a schematic configuration of a laminated sheet according to an embodiment;

FIG. 2 is a flowchart illustrating a flow of a method for manufacturing the laminated sheet according to the embodiment;

FIG. 3 is a schematic view for explaining an example of the method for manufacturing the laminated sheet;

FIG. 4 is a schematic view for explaining an example of the method for manufacturing the laminated sheet;

FIG. 5 is a perspective view illustrating a schematic configuration of a workpiece to be processed by the method for processing the workpiece according to the embodiment;

FIG. 6 is a flowchart illustrating a flow of the method for processing the workpiece according to the embodiment;

FIG. 7 is a side view illustrating a state in a sheet fixing step illustrated in FIG. 6 in a partial cross section;

FIG. 8 is a side view illustrating a state after FIG. 7 in a partial cross section;

FIG. 9 is a side view illustrating a state in a grinding step illustrated in FIG. 6 in a partial cross section;

FIG. 10 is a side view illustrating a state in the grinding step illustrated in FIG. 6 in a partial cross section;

FIG. 11 is a flowchart illustrating a flow of a method for manufacturing a device chip according to the embodiment;

FIG. 12 is a side view illustrating a state in a sheet fixing step illustrated in FIG. 11 in a partial cross section;

FIG. 13 is a side view illustrating a state in an imaging step illustrated in FIG. 11 in a partial cross section;

FIG. 14 is a side view illustrating an example of a dividing step illustrated in FIG. 11 in a partial cross section; and

FIG. 15 is a side view illustrating another example of the dividing step illustrated in FIG. 11 in a partial cross section.

### DETAILED DESCRIPTION OF THE PREFERRED EMBODIMENTS

An embodiment of the present invention will be described in detail with reference to the drawings. The present invention is not limited by contents described in the following embodiment. In addition, components described below include those that can be easily presumed by those skilled in the art and those that are substantially the same. Furthermore, configurations described below can be appropriately combined. In addition, various omissions, substitutions, or changes in the configurations can be made without departing from the gist of the present invention.

### Embodiment

### Laminated Sheet 1

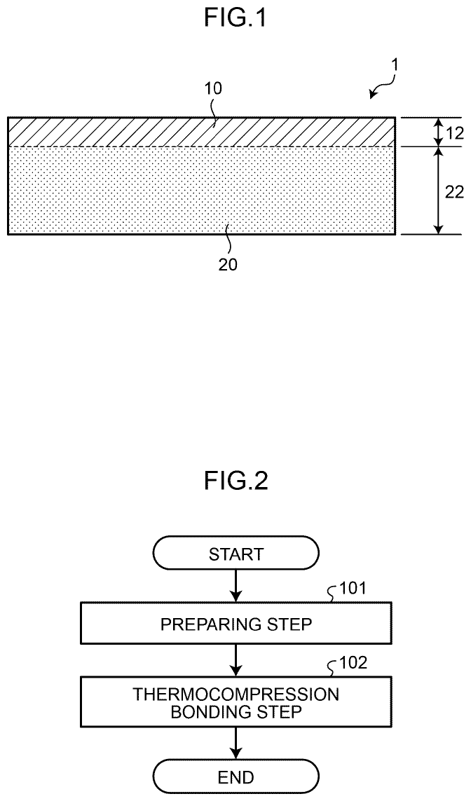

First, a laminated sheet 1 according to the embodiment of the present invention will be described with reference to FIG. 1. FIG. 1 is a cross-sectional view illustrating a schematic configuration of the laminated sheet according to the embodiment.

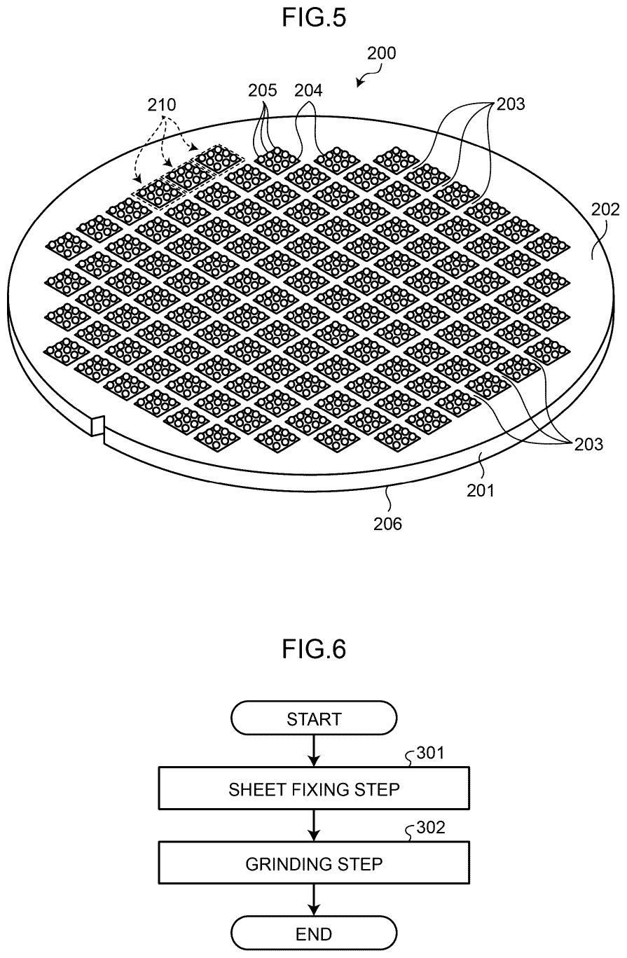

The laminated sheet 1 is, for example, a surface protection sheet that is attached to a front surface side of a workpiece such as a semiconductor wafer (for example, a workpiece 200 illustrated in FIG. 5 and the like to be described later), in order to protect the front surface side of the workpiece when a back surface side of the workpiece is processed. The laminated sheet 1 is useful particularly when protecting the front surface side of a workpiece having irregularities on the surface, but the case where the laminated sheet 1 is attached to a flat surface is not excluded.

As illustrated in FIG. 1, the laminated sheet 1 has a multilayer structure in which a first layer 10 and a second layer 20 are laminated without an adhesive layer interposed therebetween. The second layer 20 is laminated on the first layer 10. The second layer 20 side of the laminated sheet 1 is attached to the front surface side of the workpiece.

A difference in a solubility parameter (SP value) between the first layer 10 and the second layer 20 is preferably 3.0 or less, more preferably 2.0 or less, and still more preferably 1.5 or less. By setting the difference in the SP value between the first layer 10 and the second layer 20 to 3.0 or less, bonding between the first layer 10 and the second layer 20 becomes stronger, and delamination can be suppressed.

The storage modulus of the first layer 10 in the tensile direction is preferably 1.0E+9 Pa or more and 1.0E+10 Pa or less under a condition where a frequency of 1 Hz is applied in an environment of 50° C. If the storage modulus of the first layer 10 is less than 1.0E+9 Pa, the first layer 10 is too soft, and thus the first layer 10 may become wavy together with the second layer 20 following the irregularities on the surface of the workpiece when the laminated sheet 1 is attached to the workpiece. When the storage modulus of the first layer 10 is set to 1.0E+9 Pa or more, waviness of the laminated sheet 1 on the first layer 10 side can be suppressed. If the storage modulus of the first layer 10 exceeds 1.0E+10 Pa, it is difficult to select the material because there are few resins exceeding this storage modulus.

The constituent material of the first layer 10 is not particularly limited as long as the difference in the SP value between the first layer 10 and the second layer 20 and the storage modulus are within the above ranges. The first layer 10 may be made of, for example, resin such as a methacrylic resin (SP value: 9.1), polyethylene terephthalate (SP value: 10.7), polybutylene terephthalate (SP value: 10), polycarbonate, polylactic acid (SP value: 12.1), an epoxy resin (SP value: 9.7 to 10.9), or a vinyl chloride resin (SP value: 9.4 to 10.8).

The storage modulus of the second layer 20 in the tensile direction is preferably 1.0E+6 Pa or more and 1.0E+8 Pa or less, and more preferably 1.0E+7 Pa or more and 1.0E+8 Pa or less under the condition where a frequency of 1 Hz is applied in an environment of 50° C. Note that the upper limit values and the lower limit values of the storage modulus of the second layer 20 can be appropriately combined. If the storage modulus of the second layer 20 is less than 1.0E+6 Pa, the second layer 20 is too soft, which may make it difficult to peel the laminated sheet 1 from the workpiece and cause a part of the second layer 20 to remain on the workpiece. By setting the storage modulus of the second layer 20 to 1.0E+6 Pa or more, the second layer 20 can be deformed so as to sufficiently absorb the irregularities on the surface of the workpiece while allowing easy peeling from the workpiece. Furthermore, by setting the storage modulus of the second layer 20 to 1.0E+7 Pa or more, the second layer 20 can be more easily peeled from the workpiece. If the storage modulus of the second layer 20 exceeds 1.0E+8 Pa, it is difficult to attach the second layer 20 to the workpiece, and thus it is necessary to increase the temperature during affixing, which may cause the device to be damaged. By setting the storage modulus of the second layer 20 to 1.0E+8 Pa or less, the second layer 20 can be easily attached to the workpiece and deforms so as to sufficiently absorb the irregularities on the surface of the workpiece.

The material of the second layer 20 is not particularly limited as long as the difference in the SP value between the first layer 10 and the second layer 20 and the storage modulus are within the above ranges, and may be made of, for example, a synthetic resin containing polyethylene (SP value: 8.0), polypropylene (SP value: 8.0), polybutadiene (SP value: 8.3), a vinyl acetate resin (SP value: 9.2), a methacrylic resin (SP value: 9.1), a vinyl chloride resin (SP value: 9.4 to 10.8), an α-olefin, SEPS, SIS, SBS, or the like.

In the present embodiment, the storage modulus of each of the first layer 10 and the second layer 20 is measured on the following strip samples using a dynamic viscoelasticity measuring apparatus (“DMA-7100” manufactured by Hitachi High-Tech Corporation). The measurement conditions are as follows.
Sample width: 10 mm
Sample length: 20 mm
Sample thickness: 0.1 mm
Measurement mode: tension mode
Test temperature: 20° C. to 120° C. (increase by 2° C. per minute)
Frequency: 1 Hz

A thickness 12 of the first layer 10 is preferably 5 μm or more and 50 μm or less, and more preferably 10 μm or more and 20 μm or less. Note that the upper limit values and the lower limit values of the thickness 12 of the first layer 10 can be appropriately combined. The thickness 12 of the first layer 10 is preferably smaller than a thickness 22 of the second layer 20. The thickness 22 of the second layer 20 is preferably 50 μm or more and 300 μm or less, and more preferably 100 μm or more and 200 μm or less. Note that the upper limit values and the lower limit values of the thickness 22 of the second layer 20 can be appropriately combined. The thickness 22 of the second layer 20 is preferably 125% or more and 200% or less of the height of the irregularities (electrode bump 205 or the like illustrated in FIG. 5 to be described later) formed on the surface to which the laminated sheet 1 is attached.

If the thickness 12 of the first layer 10 is less than 5 μm, the cross-sectional secondary moment is too small, and thus the first layer 10 becomes wavy together with the second layer 20 following the irregularities on the surface of the workpiece when the laminated sheet 1 is attached to the workpiece. If the thickness 12 of the first layer 10 exceeds 50 μm, when the laminated sheet 1 is formed into a roll shape, the overall length of the laminated sheet 1 wound in a roll is short, which may increase the replacement frequency and the downtime. If the thickness 22 of the second layer 20 is less than 50 μm, the irregularities on the surface of the workpiece may not be sufficiently absorbed. If the thickness 22 of the second layer 20 exceeds 300 μm, when the laminated sheet 1 is formed into a roll shape, the overall length of the laminated sheet 1 wound in a roll is short, which may increase the replacement frequency and the downtime.

The thickness 12 of the first layer 10 is 5 μm or more and 50 μm or less and the thickness 22 of the second layer 20 is 50 μm or more and 300 μm or less, thereby suppressing the influence of the deformation of the second layer 20 on the first layer 10 while allowing the second layer 20 to sufficiently absorb the irregularities on the surface of the workpiece. Furthermore, the thickness 22 of the second layer 20 is 100 μm or more and 200 μm or less, thereby allowing for easier peeling from the workpiece.

### Method for Manufacturing the Laminated Sheet 1

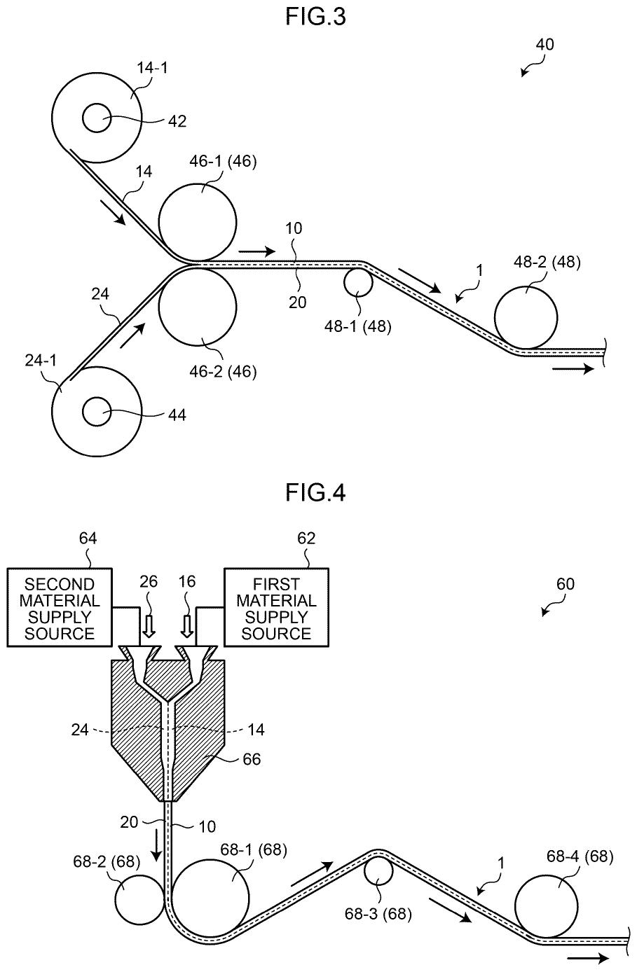

Next, a method for manufacturing the laminated sheet 1 according to the embodiment of the present invention will be described with reference to FIGS. 2 to 4. FIG. 2 is a flowchart illustrating a flow of the method for manufacturing the laminated sheet 1 according to the embodiment. FIGS. 3 and 4 are schematic views for explaining an example of the method for manufacturing the laminated sheet 1.

As illustrated in FIG. 2, the method for manufacturing the laminated sheet 1 includes a preparing step 101 and a thermocompression bonding step 102. The preparing step 101 is the step of preparing a first sheet 14 and a second sheet 24. The thermocompression bonding step 102 is the step of laminating the first sheet 14 and the second sheet 24 without an adhesive interposed therebetween, and compressing and bonding the first sheet 14 and the second sheet 24 while melting the interface therebetween by heating.

The first sheet 14 corresponds to the above-described first layer 10 when formed on the laminated sheet 1. That is, the storage modulus of the first sheet 14 in the tensile direction is preferably 1.0E+9 Pa or more and 1.0E+10 Pa or less under the condition where a frequency of 1 Hz is applied in an environment of 50° C.

The second sheet 24 corresponds to the above-described second layer 20 when formed on the laminated sheet 1. That is, the storage modulus of the second sheet 24 in the tensile direction is preferably 1.0E+6 Pa or more and 1.0E+8 Pa or less, and more preferably 1.0E+7 Pa or more and 1.0E+8 Pa or less under the condition where a frequency of 1 Hz is applied in an environment of 50° C. A difference in the SP value between the first sheet 14 and the second sheet 24 is preferably 3.0 or less, more preferably 2.0 or less, and still more preferably 1.5 or less.

In the example illustrated in FIG. 3, the laminated sheet 1 is manufactured using a laminating apparatus 40. The laminating apparatus 40 includes a first feeding roller 42, a second feeding roller 44, a pair of heating rollers 46-1 and 46-2, and supporting rollers 48-1 and 48-2. In the following description, the heating rollers 46-1 and 46-2 are simply referred to as the heating rollers 46 when they are not particularly distinguished from each other. In the following description, the supporting rollers 48-1 and 48-2 are simply referred to as the supporting rollers 48 when they are not particularly distinguished from each other.

The first feeding roller 42 is in a column shape, has an axial center thereof extending in one horizontal direction, and is rotatably supported around the axial center. The first feeding roller 42 is inserted into a core of a first sheet roll 14-1 that is the first sheet 14 in a roll shape, and supports the first sheet roll 14-1 around the axial center. The first feeding roller 42 fixes, to the outer peripheral surface thereof, the inner peripheral surface of the core of the first sheet roll 14-1 and rotates about the axial center to feed the first sheet 14 toward a gap between the heating rollers 46-1 and 46-2 on the heating roller 46-1 side.

The second feeding roller 44 is in a column shape, has an axial center thereof extending in a direction parallel to the axial center of the first feeding roller 42, and is rotatably supported around the axial center. The second feeding roller 44 is inserted into a core of a second sheet roll 24-1 that is the second sheet 24 in a roll shape, and supports the second sheet roll 24-1 around the axial center. The second feeding roller 44 fixes, to the outer peripheral surface thereof, the inner peripheral surface of the core of the second sheet roll 24-1 and rotates about the axial center to feed the second sheet 24 toward the gap between the heating rollers 46-1 and 46-2 on the heating roller 46-2 side.

Each of the heating rollers 46 includes a heat source therein. Each of the heating rollers 46 is in a column shape, has an axial center thereof extending in the direction parallel to the axial center of the first feeding roller 42, and is rotatably supported around the axial center. The pair of heating rollers 46-1 and 46-2 are disposed at positions where they are separated from each other by a predetermined distance. Between the pair of heating rollers 46-1 and 46-2, the first sheet 14 fed out from the first feeding roller 42 and the second sheet 24 fed out from the second feeding roller 44 are joined and laminated. The pair of heating rollers 46-1 and 46-2 sandwich and thermally compress the first sheet 14 and the second sheet 24 while rotating in opposite directions to each other, thereby bonding the first sheet 14 and the second sheet 24.

The outer peripheral surface of the heating roller 46-1 is in contact with one surface of the first sheet 14 to perform heating from the first sheet 14 side and apply pressure on the heating roller 46-2 side. The outer peripheral surface of the heating roller 46-2 is in contact with one surface of the second sheet 24 to perform heating from the second sheet 24 side and apply pressure on the heating roller 46-2 side. The first sheet 14 and the second sheet 24 are sandwiched and thermally compressed between the pair of heating rollers 46-1 and 46-2, whereby the other surface side of the first sheet 14 and the other surface side of the second sheet 24 are melted and bonded, and then the laminated sheet 1 is manufactured. Note that the surface of each of the heating rollers 46 may be coated with fluororesin.

The supporting roller 48 is in a column shape, has an axial center extending in the direction parallel to the axial center of the first feeding roller 42, and is rotatably supported around the axial center. The plurality of supporting rollers 48-1 and 48-2 convey the laminated sheet 1 from the heating rollers 46 to a winding roller (not illustrated) that winds up the manufactured laminated sheet 1 in a roll shape, and apply a tension for suppressing loosening of the laminated sheet 1 to the laminated sheet 1. At the downstream of the heating roller 46-2, the supporting roller 48-1 of the embodiment is in contact with the second sheet 24 (second layer 20) side of the laminated sheet 1 to apply pressure on the first sheet 14 (first layer 10) side. At the downstream of the heating roller 46-1 and the supporting roller 48-1, the supporting roller 48-2 of the embodiment is in contact with the first sheet 14 (first layer 10) side of the laminated sheet 1 to apply pressure on the second sheet 24 (second layer 20) side. The laminated sheet 1 heated by the heating rollers 46 is cooled under a normal temperature environment, for example, while being conveyed by the supporting rollers 48. The supporting roller 48 may include a cooling source that cools the laminated sheet 1.

In a case where the laminated sheet 1 is manufactured by the laminating apparatus 40 illustrated in FIG. 3, the preparing step 101 corresponds to, for example, preparing the first sheet roll 14-1 and the second sheet roll 24-1, or feeding out the first sheet 14 and the second sheet 24 from the first sheet roll 14-1 and the second sheet roll 24-1. The thermocompression bonding step 102 corresponds to performing thermocompression bonding using the pair of heating rollers 46-1 and 46-2.

In the example illustrated in FIG. 4, the laminated sheet 1 is manufactured using an extruding apparatus 60. The extruding apparatus 60 includes a first material supply source 62, a second material supply source 64, a T-die 66, and supporting rollers 68-1, 68-2, 68-3, and 68-4. In the following description, the supporting rollers 68-1, 68-2, 68-3, and 68-4 are simply referred to as the supporting rollers 68 when they are not particularly distinguished from each other.

The first material supply source 62 supplies a first material 16 that is a constituent material of the first layer 10 to the T-die 66. The first material 16 may be supplied in pellet, granular, or powder form. The second material supply source 64 supplies a second material 26 that is a constituent material of the second layer 20 to the T-die 66. The second material 26 may be supplied in pellet, granular, or powder form.

The T-die 66 of the embodiment is divided into two layers at the upstream therein, and the first material 16 and the second material 26 are supplied to the respective layers. The T-die 66 heats and melts the first material 16 supplied from the first material supply source 62, and spreads the first material 16 into a sheet shape to form the first sheet 14. The T-die 66 heats and melts the second material 26 supplied from the second material supply source 64, and spreads the second material 26 into a sheet shape to form the second sheet 24. The two layers are joined inside the T-die 66. The joined first sheet 14 and second sheet 24 are in a laminated state. The laminated first sheet 14 and second sheet 24 are co-extruded while being heated inside the T-die 66, and are thereby thermocompression-bonded. As a result, the melted interface is bonded and then the laminated sheet 1 is manufactured. The laminated sheet 1 is discharged from an extrusion port (a slit at a lower end) of the T-die 66.

Each of the supporting rollers 68 is in a column shape, has a horizontal axial center extending in a direction parallel to a surface of the laminated sheet 1 discharged from the T-die 66, and is rotatably supported around the axial center. The plurality of supporting rollers 68-1, 68-2, 68-3, and 68-4 convey the laminated sheet 1 from the T-die 66 to a winding roller (not illustrated) that winds up the manufactured laminated sheet 1 in a roll shape, and apply a tension for suppressing loosening of the laminated sheet 1 to the laminated sheet 1. At the downstream of the T-die 66, the supporting roller 68-1 of the embodiment is in contact with the first sheet 14 (first layer 10) side of the laminated sheet 1 to apply pressure on the second sheet 24 (second layer 20) side. At a position facing the supporting roller 68-1, the supporting roller 68-2 of the embodiment is in contact with the second sheet 24 (second layer 20) side of the laminated sheet 1 to apply pressure on the first sheet 14 (first layer 10) side. At the downstream of the supporting rollers 68-1 and 68-2, the supporting roller 68-3 of the embodiment is in contact with the second sheet 24 (second layer 20) side of the laminated sheet 1 to apply pressure on the first sheet 14 (first layer 10) side. At the downstream of the supporting roller 68-3, the supporting roller 68-4 of the embodiment is in contact with the first sheet 14 (first layer 10) side of the laminated sheet 1 to apply pressure on the second sheet 24 (second layer 20) side. The laminated sheet 1 heated by the T-die 66 is cooled, for example, when the water-cooled supporting rollers 68-1 and 68-2 are pressed against the laminated sheet 1. The supporting rollers 68 are made of SUS, for example.

When the laminated sheet 1 is manufactured by the extruding apparatus 60 illustrated in FIG. 4, the preparing step 101 corresponds to, for example, molding the first sheet 14 and the second sheet 24 from the first material 16 and the second material 26 inside the T-die 66. The thermocompression bonding step 102 corresponds to laminating the first sheet 14 and the second sheet 24 inside the T-die 66 and co-extruding them.

### Workpiece 200

Next, the workpiece 200 to be processed by a method for processing the workpiece 200 according to the embodiment of the present invention will be described with reference to FIG. 5. FIG. 5 is a perspective view illustrating a schematic configuration of the workpiece 200 to be processed by the method for processing the workpiece 200 according to the embodiment.

As illustrated in FIG. 5, the workpiece 200 is a semiconductor wafer made of a material such as silicon (Si), silicon carbide (SiC), gallium nitride (GaN), gallium arsenide (GaAs), or other semiconductors, a wafer such as an optical device wafer, a substantially disk-shaped substrate made of a material such as sapphire (Al2O3), lithium tantalate (LiTaO3), glass, or quartz, or the like. The glass includes, for example, alkali glass, alkali-free glass, soda lime glass, lead glass, borosilicate glass, quartz glass, and the like. In the embodiment, a substrate 201 of the workpiece 200 is 775 μm in thickness from a front surface 202 to a back surface 206.

As illustrated in FIG. 5, the workpiece 200 has a plurality of planned division lines 203 set in a lattice shape and devices 204 formed on the front surface 202 side in a region sectioned by the intersecting planned division lines 203. The device 204 is, for example, an integrated circuit such as an integrated circuit (IC) or a large scale integration (LSI), an image sensor such as a charge coupled device (CCD) or a complementary metal oxide semiconductor (CMOS), a micro electro mechanical systems (MEMS), a memory (semiconductor storage device), or the like.

In the embodiment, a plurality of electrode bumps 205 that are protrusions protruding from the surface of the device 204 are mounted on the front surface 202 of the substrate 201 of the workpiece 200. Since the electrode bumps 205 are mounted, the workpiece 200 has irregularities on the front surface 202. Each of the electrode bumps 205 is electrically connected to the device 204, and functions as an electrode when an electric signal is input to and output from the device 204 in a state where the workpiece 200 is divided to form the device chip 210. The electrode bump 205 is made of, for example, a metal material such as gold, silver, copper, or aluminum. The electrode bump 205 is 100 μm or more and 300 μm or less high, and protrudes from the surface of the device 204. The electrode bump 205 of the embodiment is 200 μm high.

The workpiece 200 is divided into the individual devices 204 along the planned division lines 203 and singulated into the device chips 210. The device chip 210 includes a portion of the substrate 201 and the device 204. In the embodiment, the device 204 includes the electrode bumps 205, and the workpiece 200 is divided into the device chips 210 to be mounted on the mounting substrate by a mounting technique called flip chip bonding.

In FIG. 5, the device chip 210 is in a square shape, but may be in a rectangular shape. In the embodiment, the workpiece 200 has the irregularities on the front surface 202 since the electrode bumps 205 protruding from the surface of the device 204 are mounted. However, the method for processing the workpiece 200 of the present invention is useful for the workpiece 200 having irregularities on the front surface 202 without being limited to the electrode bumps 205.

### Method for Processing the Workpiece 200

Next, the method for processing the workpiece 200 according to the embodiment of the present invention will be described with reference to FIGS. 6 to 10. FIG. 6 is a flowchart illustrating a flow of the method for processing the workpiece 200 according to the embodiment. As illustrated in FIG. 6, the method for processing the workpiece 200 includes a sheet fixing step 301 and a grinding step 302.

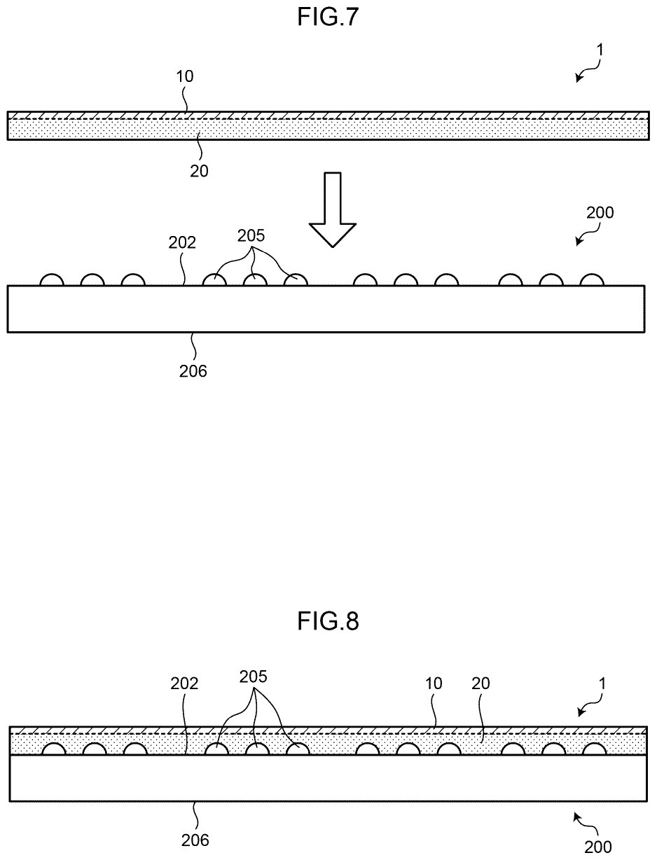

FIG. 7 is a side view illustrating a state in the sheet fixing step 301 illustrated in FIG. 6 in a partial cross section. FIG. 8 is a side view illustrating a state after FIG. 7 in a partial cross section. The sheet fixing step 301 is the step of fixing the second layer 20 side of the laminated sheet 1 to the front surface 202 side of the workpiece 200.

As illustrated in FIGS. 7 and 8, in the sheet fixing step 301, the second layer 20 side of the laminated sheet 1 and the front surface 202 side of the workpiece 200 are set so as to face each other, and then the second layer 20 side of the laminated sheet 1 is attached to the front surface 202 side of the workpiece 200. At this time, in the sheet fixing step 301, the second layer 20 side of the laminated sheet 1 is attached to the front surface 202 side of the workpiece 200 while the laminated sheet 1 is heated.

The sheet fixing step 301 may be performed, for example, in a state where the back surface 206 of the workpiece 200 is placed on a holding surface of a holding table (not illustrated). The holding table may be a heat table including a heating source capable of heating the holding surface. In the sheet fixing step 301, first, the back surface 206 of the workpiece 200 is held on the holding table, and then the second layer 20 side of the laminated sheet 1 is set so as to face the front surface 202 side of the workpiece 200.

In the sheet fixing step 301, next, the laminated sheet 1 is placed on and pressed to the front surface 202 side of the workpiece 200. A method for pressing the laminated sheet 1 to the front surface 202 side of the workpiece 200 includes, for example, pressing with a pressing roller (not illustrated) that rolls from one end portion of the workpiece 200 toward the other end portion. The pressing roller may be a heat roller including a heating source therein. The sheet fixing step 301 may be performed in a state where the first layer 10 side of the laminated sheet 1 is placed on the holding surface of the holding table.

In the sheet fixing step 301, the laminated sheet 1 is pressed in a direction in which it is spread while at least one of the laminated sheet 1 and the workpiece 200 is heated, thereby performing thermocompression bonding of the laminated sheet 1 to the workpiece 200. As a result, the second layer 20 side of the laminated sheet 1 and the front surface 202 side of the workpiece 200 are compressed and bonded to each other, and the second layer 20 side of the laminated sheet 1 is fixed to the front surface 202 side of the workpiece 200.

Note that for example, the thermocompression bonding of the laminated sheet 1 to the workpiece 200 may be performed using, without being limited to the heat roller, a pressing unit (not illustrated) having a flat and horizontal pressing surface facing the holding surface of the heat table on the lower surface thereof and capable of moving up and down relative to the heat table. The pressing unit may include a heating source capable of heating the pressing surface. When thermocompression-bonded by the heat table, heat roller, or pressing unit, the laminated sheet 1 is preferably heated to a temperature of a softening point or more and a melting point or less.

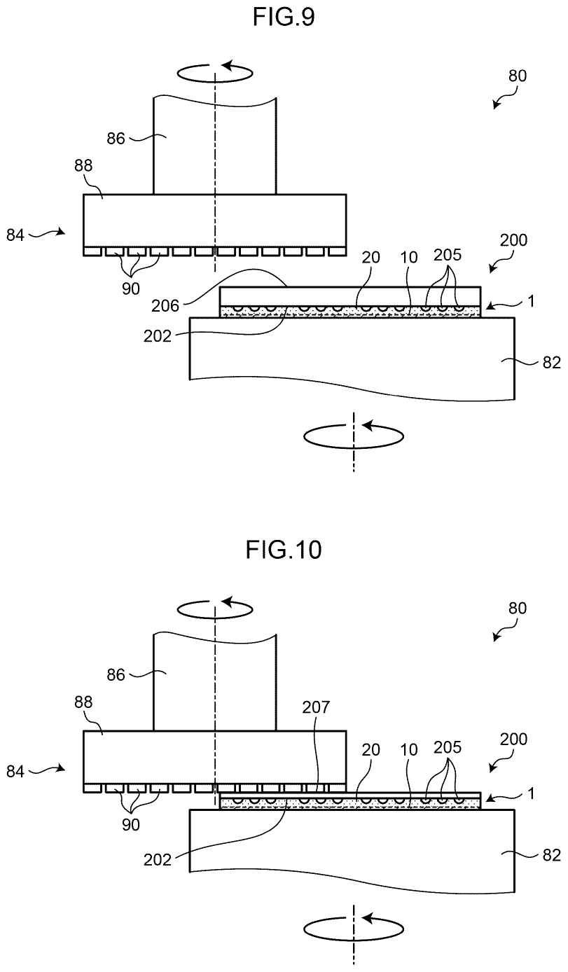

FIGS. 9 and 10 are side views illustrating a state in the grinding step 302 illustrated in FIG. 6 in a partial cross section. The grinding step 302 is performed after the sheet fixing step 301 is performed. The grinding step 302 is the step of grinding the back surface 206 side of the workpiece 200.

As illustrated in FIGS. 9 and 10, the grinding step 302 of the embodiment is performed by a grinding apparatus 80. The grinding apparatus 80 includes a holding table 82, a grinding unit 84, and a grinding liquid supply unit (not illustrated). The grinding unit 84 includes a spindle 86 that is a rotary shaft member, a grinding wheel 88 attached to the lower end of the spindle 86, and a grinding stone 90 attached to the lower surface of the grinding wheel 88. The spindle 86 rotates about a rotation axis parallel to the axial center of the holding table 82.

As illustrated in FIG. 9, in the grinding step 302, first, the laminated sheet 1 side of the workpiece 200 to which the laminated sheet 1 is fixed is sucked to and held on a holding surface of the holding table 82. That is, the first layer 10 side of the laminated sheet 1 is sucked and held. Next, the spindle 86 and the grinding wheel 88 are rotated about the axial center while the holding table 82 is rotated about the axial center. By supplying grinding liquid to the processing point using the grinding liquid supply unit (not illustrated) and bringing the grinding stone 90 of the grinding wheel 88 close to the holding table 82 at a predetermined feed speed, the back surface 206 side of the workpiece 200 is ground by the grinding stone 90 and thinned to a predetermined finished thickness.

After the grinding step 302 is performed, for example, dicing is performed along the planned division lines 203 (see FIG. 5) to singulate the workpiece 200 into the device chips 210 (see FIG. 5) obtained by dividing the workpiece 200 into the individual devices 204. At this time, by allowing a cutting blade to cut in from a grinding surface 207 side of the workpiece 200 so as not to divide the laminated sheet 1, the device chips 210 can be suppressed from being scattered during cutting processing. The singulated device chips 210 are peeled off and removed from the laminated sheet 1 one by one or in a plurality of numbers at a time by a pickup apparatus, for example.

The grinding step 302 may be performed on the workpiece 200, for example, on which division starting points are formed along the planned division lines 203. The division starting point includes, for example, a modified layer formed inside the workpiece 200 by laser processing and a processed groove formed on the front surface 202 side of the workpiece 200 by cutting processing. Note that, when the processed groove is formed on the front surface 202 side of the workpiece 200, the division starting point is formed before the sheet fixing step 301.

As described above, by performing the grinding step 302 on the workpiece 200 in which the division starting points are formed along the planned division lines 203, the workpiece 200 is divided along the planned division lines 203 using the division starting points as starting points under an external force of the grinding stone 90 pressing the grinding surface 207 of the workpiece 200, and is singulated into the device chips 210.

### Method for Manufacturing the Device Chip

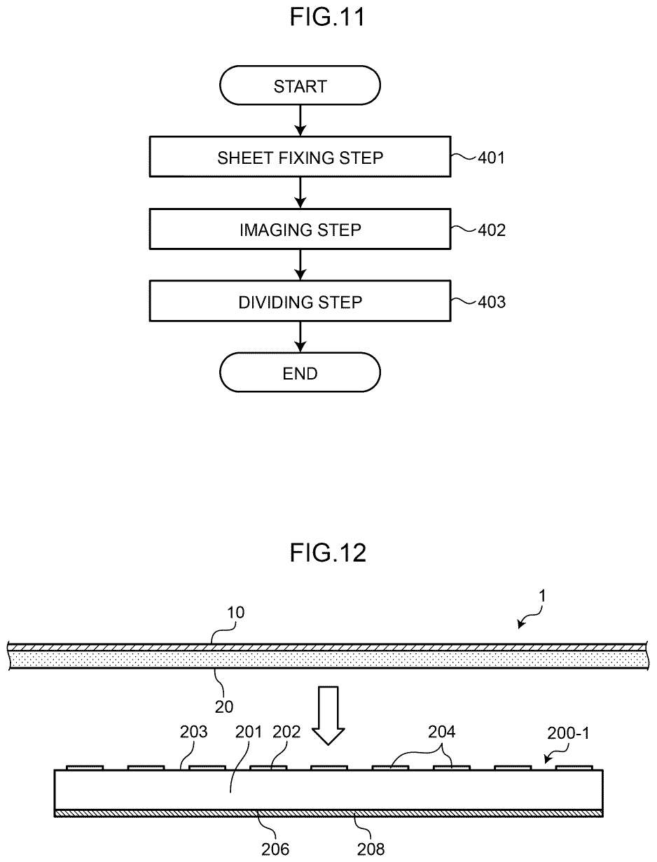

Next, a method for manufacturing a device chip 210-1 according to the embodiment of the present invention will be described with reference to FIGS. 11 to 15. FIG. 11 is a flowchart illustrating a flow of the method for manufacturing the device chip according to the embodiment. As illustrated in FIG. 11, the method for manufacturing the device chip 210-1 includes a sheet fixing step 401, an imaging step 402, and a dividing step 403.

FIG. 12 is a side view illustrating a state in the sheet fixing step illustrated in FIG. 11 in a partial cross section. The sheet fixing step 401 is the step of fixing the second layer 20 side of the laminated sheet 1 to the front surface 202 or the back surface 206 of a workpiece 200-1. In the sheet fixing step 401 of the embodiment, the second layer 20 side of the laminated sheet 1 is fixed to the front surface 202 of the workpiece 200-1.

Here, the workpiece 200-1 to be processed by the method for manufacturing the device chip 210-1 according to the embodiment will be described. The basic configuration of the workpiece 200-1 is the same as that of the above-described workpiece 200, but the electrode bump 205 is not mounted on the workpiece 200-1, and instead, a film 208 is formed on the back surface 206 opposite to the front surface 202 on which the device 204 is formed. In the workpiece 200-1 of the embodiment, the entire back surface 206 is covered with the film 208 having a substantially constant thickness. The film 208 is, for example, a metal layer or may be an oxide film.

The method for manufacturing the device chip 210-1 is a method for manufacturing the device chip 210-1 by dividing, along the planned division lines 203, the workpiece 200-1 having the planned division lines 203 set on the front surface 202. The object to be processed by the method for manufacturing the device chip 210-1 is not limited to the workpiece 200-1 on which the electrode bump 205 is not mounted, and may be the workpiece 200 on which the electrode bump 205 is mounted. In addition, the object to be processed is not limited to the workpiece 200-1 on which the film 208 is formed on the back surface 206, and may be the workpiece 200 on which the film 208 is not formed on the back surface 206.

The sheet fixing step 401 of the method for manufacturing the device chip 210-1 is performed by the same method and procedure as those of the sheet fixing step 301 of the above-described method for processing the workpiece 200. That is, as illustrated in FIG. 12, in the sheet fixing step 401, the second layer 20 side of the laminated sheet 1 and the front surface 202 side of the workpiece 200-1 are set so as to face each other, and then the second layer 20 side of the laminated sheet 1 is attached to the front surface 202 side of the workpiece 200-1. At this time, in the sheet fixing step 401, the second layer 20 side of the laminated sheet 1 is attached to the front surface 202 side of the workpiece 200-1 while the laminated sheet 1 is heated.

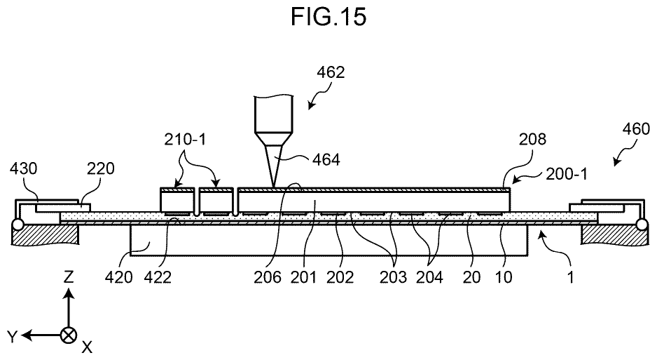

At the same time or before or after this, in the sheet fixing step 401, the outer periphery, which is radially outside the workpiece 200-1, of the laminated sheet 1 to be attached to the workpiece 200-1 is attached to an annular frame 220 (see FIG. 14 or 15 to be described later). The frame 220 is an annular plate member made of metal or resin and having an opening larger than the outer diameter of the workpiece 200-1. Thus, the frame 220 supports the workpiece 200-1 via the laminated sheet 1.

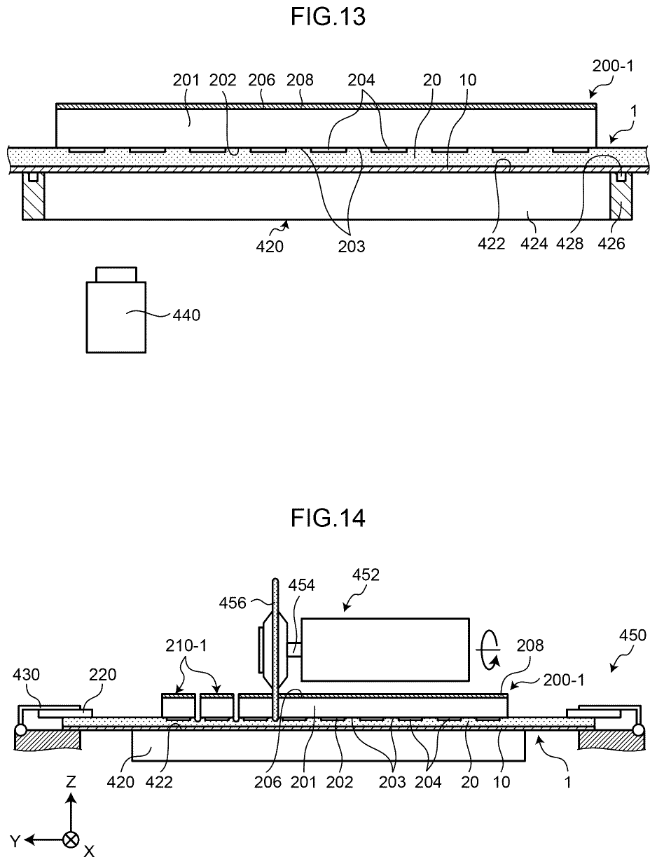

FIG. 13 is a side view illustrating a state in the imaging step illustrated in FIG. 11 in a partial cross section. The imaging step 402 is performed after the sheet fixing step 401 and before the dividing step 403. The imaging step 402 is the step of imaging, via the laminated sheet 1 fixed to the front surface 202 side of the workpiece 200-1, the planned division lines 203 set on the front surface 202 of the workpiece 200-1.

In the imaging step 402, first, the front surface 202 side of the workpiece 200-1 is held on a holding surface 422 of a holding table 420 via the laminated sheet 1. At this time, the first layer 10 side of the laminated sheet 1 is held on the holding surface 422 of the holding table 420. Since the first layer 10 is harder than the second layer 20, adhesion to the holding surface 422 can be reduced. The holding table 420 is formed such that at least a part of the holding surface 422 includes a transparent member 424 that is a transparent body. The holding table 420 includes, for example, the disk-shaped transparent member 424 and an annular frame body 426 that holds the outer edge of the transparent member 424.

The transparent member 424 is made of a transparent material such as quartz glass, borosilicate glass, sapphire, calcium fluoride, lithium fluoride, or magnesium fluoride, and is formed in a disk shape with a constant thickness. The outer diameter of the transparent member 424 is formed to be larger than the outer diameter of the workpiece 200-1 and smaller than the inner diameter of the opening of the frame 220 (see FIG. 14 or 15 to be described later). The transparent member 424 has an outer edge supported by the frame body 426, and is exposed above and below the holding table 420.

The frame body 426 is made of, for example, metal such as stainless steel. The frame body 426 has an inner diameter equal to the outer diameter of the transparent member 424, and is attached to the outer edge of the transparent member 424. The upper surface of the frame body 426 is formed flat along the horizontal direction and is disposed on the same plane as the holding surface 422. The frame body 426 includes, on the inner edge portion of the upper surface thereof, a suction groove 428 recessed from the upper surface and having an annular planar shape. The suction groove 428 is connected to a suction source (not illustrated) via a suction path (not illustrated) formed so as to penetrate through the frame body 426. In the holding table 420, when the suction source (not illustrated) sucks the suction groove 428 via the suction path, the workpiece 200 and the frame 220 are sucked to and held on the holding surface 422 (the upper surface of the frame body 426) via the laminated sheet 1.

The holding table 420 may include a clamp member 430 (see FIG. 14 or 15 to be described later) disposed around the holding surface 422. The clamp member 430 clamps the frame 220.

In the imaging step 402, an imaging apparatus 440 is disposed below the holding table 420. The imaging apparatus 440 includes an imaging element that images the front surface 202 of the workpiece 200-1 via the transparent member 424 and the laminated sheet 1. The imaging element is, for example, a CCD imaging element or a CMOS imaging element. The imaging apparatus 440 images the front surface 202 of the workpiece 200-1 via the transparent member 424 and the laminated sheet 1. Next, in the imaging step 402, the imaging apparatus 440 images the front surface 202 of the workpiece 200-1 to detect the planned division lines 203.

The imaging step 402 is useful particularly in a case where the film 208 made of metal or the like is formed on the back surface 206 as in the embodiment, and alignment from the back surface 206 is difficult. The holding table 420 that supports the workpiece 200-1 in the imaging step 402 is preferably the same as the holding table 420 of the processing apparatus (a cutting apparatus 450 illustrated in FIG. 14 or a laser processing apparatus 460 illustrated in FIG. 15) that performs the next dividing step 403.

FIG. 14 is a side view illustrating an example of the dividing step illustrated in FIG. 11 in a partial cross section. The dividing step 403 is performed after the sheet fixing step 401 is performed. The dividing step 403 is the step of dividing the workpiece 200-1 along the planned division lines 203 by processing the workpiece 200-1 from the surface (back surface 206 in the embodiment) opposite to the surface to which the laminated sheet 1 is fixed (front surface 202 in the embodiment).

In the example illustrated in FIG. 14, the cutting processing of cutting the workpiece 200-1 along the planned division lines 203 is performed using the cutting apparatus 450. The cutting apparatus 450 includes the holding table 420 and a cutting unit 452. The cutting apparatus 450 further includes a cutting liquid supply unit that supplies cutting water to the processing point, a moving unit and a rotating unit (not illustrated) that relatively move the holding table 420 and the cutting unit 452, a control unit that controls each constituent component and unit, and the like.

In the embodiment, the holding table 420 is the same as the holding table 420 in the imaging step 402. The holding table 420 can be relatively moved by the moving unit (not illustrated) in a processing feed direction (X-axis direction), an indexing feed direction (Y-axis direction), and a cut-in feed direction (Z-axis direction) with respect to the cutting unit 452. The holding table 420 can be rotated by the rotating unit (not illustrated) about an axial center parallel to the Z-axis direction.

The cutting unit 452 is a unit that performs cutting processing on the workpiece 200-1 held on the holding table 420. The cutting unit 452 includes a spindle 454 and a cutting blade 456. The spindle 454 is provided so as to be rotatable about an axial center parallel to the Y-axis direction, and the cutting blade 456 is attached to the end of the spindle 454 so as to be coaxial. The cutting blade 456 is a processing tool for forming a cutting groove in the workpiece 200-1, and is a cutting grindstone having a cutting edge made of diamond abrasive grains or CBN (Cubic Boron Nitride) abrasive grains solidified with a bonding material such as metal or resin, and formed in an extremely thin disk shape and an annular shape.

In the dividing step 403 by the cutting processing illustrated in FIG. 14, the front surface 202 side of the workpiece 200-1 is held on the holding surface 422 of the holding table 420 via the laminated sheet 1 continuously from the imaging step 402. In the dividing step 403, first, the planned division lines 203 are detected based on the captured image of the front surface 202 of the workpiece 200-1 captured in the imaging step 402, and alignment for aligning the holding table 420 and the cutting blade 456 is performed by the moving unit (not illustrated). Specifically, the processing point of the cutting blade 456 is positioned above the planned division line 203 of the workpiece 200-1.

In the dividing step 403, next, the supply of the cutting liquid toward the processing point of the cutting blade 456 is started, and the rotation of the spindle 454 is started. Next, while the holding table 420 is fed for processing in the X-axis direction, the cutting edge of the cutting blade 456 is cut in to the laminated sheet 1 attached to the front surface 202 side of the workpiece 200-1. As a result, the workpiece 200-1 is divided along the planned division lines 203 and singulated into the device chips 210-1. As described above, in the dividing step 403 of the embodiment, based on the positions of the planned division lines 203 imaged in the imaging step 402, the workpiece 200-1 is processed from the back surface 206 side along the planned division lines 203.

FIG. 15 is a side view illustrating another example of the dividing step illustrated in FIG. 11 in a partial cross section. In the example illustrated in FIG. 15, the laser processing of cutting the workpiece 200-1 along the planned division lines 203 is performed using the laser processing apparatus 460. The laser processing apparatus 460 includes the holding table 420 and a laser beam irradiation unit 462. In addition, the laser processing apparatus 460 further includes: a moving unit and a rotating unit (not illustrated) that relatively move the holding table 420 and at least a light focuser of the laser beam irradiation unit 462, a control unit that controls each constituent component and unit, and the like.

In the embodiment, the holding table 420 is the same as the holding table 420 in the imaging step 402. The holding table 420 can be relatively moved by the moving unit (not illustrated) in the processing feed direction (X-axis direction), the indexing feed direction (Y-axis direction), and the light collection point position adjustment direction (Z-axis direction) with respect to the laser beam irradiation unit 462. The holding table 420 can be rotated by the rotating unit (not illustrated) about an axial center parallel to the Z-axis direction.

The laser beam irradiation unit 462 is a unit that irradiates the workpiece 200-1 held on the holding table 420 with a laser beam 464. The laser beam irradiation unit 462 includes an oscillator that emits the laser beam 464, the light focuser that focuses the laser beam 464 toward the holding table 420, and various optical elements disposed in an optical path between the oscillator and the light focuser. The laser beam 464 is a laser beam having a wavelength that is absorptive to the workpiece 200-1, for example, ultraviolet (UV) light.

In the dividing step 403 by the laser processing illustrated in FIG. 15, the front surface 202 side of the workpiece 200-1 is held on the holding surface 422 of the holding table 420 via the laminated sheet 1 continuously from the imaging step 402. In the dividing step 403, first, the planned division lines 203 are detected based on the captured image of the front surface 202 of the workpiece 200-1 captured in the imaging step 402, and alignment for aligning the holding table 420 and the light focuser of the laser beam irradiation unit 462 is performed by the moving unit (not illustrated). Specifically, the position (focus point) to be irradiated with the laser beam 464 is positioned on the back surface 206 of the workpiece 200-1, and the horizontal direction is aligned with the planned division line 203. The focus point of the laser beam 464 may be positioned (defocused) at a position displaced in the height direction from the back surface 206 of the workpiece 200-1 by a predetermined amount.

In the dividing step 403, next, the laser beam 464 is emitted from the back surface 206 side of the workpiece 200-1 while relatively moving (feeding for processing) the planned division line 203 and the focus point of the laser beam 464 along the X-axis direction by the moving unit (not illustrated). As a result, the workpiece 200-1 is divided along the planned division lines 203 and singulated into the device chips 210-1. In this manner, in the dividing step 403 of the embodiment, processing is performed on the workpiece 200-1 from the back surface 206 side of the workpiece 200-1 along the planned division lines 203 based on the positions of the planned division lines 203 imaged in the imaging step 402.

As described above, since the laminated sheet 1 according to the embodiment has no adhesive layer, thickness variation does not occur during grinding, polishing, or the like due to the thickness variation of the adhesive layer, and thus the laminated sheet 1 according to the embodiment provides the effect of reducing the thickness variation as a whole. In addition, since the workpiece 200 is not contaminated due to the exudation of the adhesive layer, the laminated sheet 1 according to the embodiment provides the effect of reducing the environmental load in addition to reduction of a product defect. In addition, when imaging is performed through the sheet supporting the workpiece 200-1 (laminated sheet 1) as in the method for manufacturing the device chip 210-1 according to the above-described embodiment, the laminated sheet 1 according to the embodiment provides the effect of facilitating imaging due to the absence of the adhesive layer.

Note that the present invention is not limited to the above-described embodiment. That is, various modifications can be made without departing from the gist of the present invention.

For example, in the method for manufacturing the device chip 210-1 according to the embodiment, the workpiece 200-1 having the film 208 on the back surface 206 side is processed from the back surface 206 side, but a workpiece not having the film 208 may be processed from the front surface 202 side. In addition, in the imaging step 402, the laminated sheet 1 may be held on the holding table 420 so as to be exposed, and imaged from above. In this case, a part of the holding surface 422 of the holding table 420 may not be the transparent member 424.

According to the present disclosure, it is possible to reduce the thickness variation while sufficiently protecting the wafer surface when grinding the wafer.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A laminated sheet comprising:
a first layer having a storage modulus of 1.0E+9 Pa or more and 1.0E+10 Pa or less in a tensile direction under a condition where a frequency of 1 Hz is applied in an environment of 50°C.; and
a second layer laminated on the first layer and having a storage modulus of 1.0E+6 Pa or more and 1.0E+8 Pa or less in the tensile direction under the condition where the frequency of 1 Hz is applied in the environment of 50°C.,
wherein
a difference in a solubility parameter between the first layer and the second layer is 3.0 or less, and
the first layer and the second layer are laminated without an adhesive layer interposed therebetween.

2. The laminated sheet according to claim 1, wherein a thickness of the first layer is smaller than a thickness of the second layer.

3. A method for processing a workpiece having irregularities on a front surface,
the method comprising:
fixing the second layer side of the laminated sheet according to claim 1 to the front surface side of the workpiece; and
grinding a back surface side of the workpiece after the fixing.

4. A method for manufacturing a device chip by dividing a workpiece along planned division lines set on a front surface of the workpiece,
the method comprising:
fixing the second layer side of the laminated sheet according to claim 1 to the front surface or a back surface of the workpiece; and
after the fixing, dividing the workpiece along the planned division lines by processing the workpiece from the first surface or the back surface opposite to the surface to which the laminated sheet is fixed.

5. The method for manufacturing a device chip according to claim 4, wherein the fixing includes fixing the second layer side of the laminated sheet to the front surface of the workpiece.

6. The method for manufacturing a device chip according to claim 5, wherein a film is formed on the back surface of the workpiece.

7. The method for manufacturing a device chip according to claim 5, further comprising
imaging, via the laminated sheet fixed to the front surface side of the workpiece, the planned division lines set on the front surface of the workpiece,
wherein the dividing includes processing the workpiece from the back surface side along the planned division lines based on positions of the planned division lines imaged in the imaging.

8. A method for manufacturing a laminated sheet,
the method comprising:
preparing a first sheet and a second sheet, the first sheet having a storage modulus of 1.0E+9 Pa or more and 1.0E+10 Pa or less in a tensile direction under a condition where a frequency of 1 Hz is applied in an environment of 50°C., and the second sheet having a storage modulus of 1.0E+6 Pa or more and 1.0E+8 Pa or less in the tensile direction under the condition where the frequency of 1 Hz is applied in the environment of 50°C. and having a difference in a solubility parameter from the first sheet of 3.0 or less; and
laminating the first sheet and the second sheet without an adhesive interposed therebetween, and compressing and bonding the first sheet and the second sheet while melting an interface therebetween by heating.

9. A method for processing a workpiece having irregularities on a front surface,
the method comprising:
fixing the second layer side of the laminated sheet according to claim 8 to the front surface side of the workpiece; and
grinding a back surface side of the workpiece after the fixing.

10. A method for manufacturing a device chip by dividing a workpiece along planned division lines set on a front surface of the workpiece,
the method comprising:
fixing the second layer side of the laminated sheet according to claim 8 to the front surface or a back surface of the workpiece; and
after the fixing, dividing the workpiece along the planned division lines by processing the workpiece from the first surface or the back surface opposite to the surface to which the laminated sheet is fixed.

11. The method for manufacturing a device chip according to claim 10, wherein the fixing includes fixing the second layer side of the laminated sheet to the front surface of the workpiece.

12. The method for manufacturing a device chip according to claim 11, wherein a film is formed on the back surface of the workpiece.

13. The method for manufacturing a device chip according to claim 11, further comprising
imaging, via the laminated sheet fixed to the front surface side of the workpiece, the planned division lines set on the front surface of the workpiece,
wherein the dividing includes processing the workpiece from the back surface side along the planned division lines based on positions of the planned division lines imaged in the imaging.
